(19) United States
(12) Patent Application Publication
(10) Pub. No.: US 2026/0311794 A1
(43) Pub. Date: Oct. 8, 2026

(54) ARTIFICIAL INTELLIGENCE ENGINE ARRAY WITH REDUNDANT COLUMN

(71) Applicant: XILINX, INC., San Jose, CA (US)

(72) Inventors: Juan J. NOGUERA SERRA, San Jose, CA (US); Alejandro RICO CARRO, Austin, TX (US); David Patrick CLARKE, Dublin (IE)

(21) Appl. No.: 19/169,617

(22) Filed: Apr. 3, 2025

(51) Int. Cl. G11C 29/00; G11C 29/02

(52) U.S. Cl. CPC G11C 29/702; G11C 29/022; G11C 29/76

(57) ABSTRACT

Embodiments herein describe an artificial intelligence (AI) engine an array of tiles configured to form multiple rows and columns, where at least one column of the array of tiles is a redundant column and a bypass circuit configured to detect a defective column of the array of tiles and re-route at least signals, operations, memory interfaces, or data flows from the defective column to the redundant column. The bypass circuit includes defect detection circuitry configured to monitor chip components and flag defects, multiplexers and switches to re-route the signals, operations, or data flows from the defective column to the redundant column, and control logic for orchestrating re-routing decisions.

### TECHNICAL FIELD

Examples of the present disclosure generally relate to artificial intelligence (AI) engines, and, in particular, to an AI engine with at least one redundant column in the AI engine array.

### BACKGROUND

Artificial intelligence (AI) engines including AI engine (AIE) arrays handle computationally intensive tasks like machine learning, data analytics, and neural network inference. An AIE array typically includes multiple interconnected processing elements, each optimized for parallel execution and high throughput. AIE arrays are embedded within larger system-on-chip (SoC) architectures to accelerate AI workloads with speed and efficiency.

However, defects introduced during the manufacturing or operational phases can render portions of an AIE array inoperable, potentially compromising the functionality of the entire chip. Even a single defective processing element or interconnect within the AIE array can lead to reduced performance or complete failure of the chip. Solutions that enable the identification, isolation, and recovery from defects are beneficial for improving yield, reliability, and cost-efficiency in AI-enabled systems.

### SUMMARY

One example described herein is a system including an array of tiles configured to form multiple rows and columns, where at least one column of the array of tiles is a redundant column and a bypass circuit configured to detect a defective column of the array of tiles and re-route at least signals, operations, memory interfaces, or data flows from the defective column to the redundant column.

One example described herein is a method including forming an array of tiles with multiple rows and columns, where at least one column of the array of tiles is a redundant column, detecting a defective column of the array of tiles using a bypass circuit, and re-routing at least signals, operations, memory interfaces, or data flows from the defective column to the redundant column.

One example described herein is a system-on-chip (SoC) including one or more artificial intelligence (AI) engines, each AI engine including an array of tiles with multiple rows and columns and a bypass circuit configured to detect a defective column of the array of tiles and re-route communication and computation operations (resources including compute, interconnect, and memory interfaces) from the defective column to the redundant column.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A illustrates a system including an artificial intelligence engine (AIE) array having a redundant column, according to an example.

FIG. 1B illustrates the AI engine array of FIG. 1A including the redundant column where a defect has been detected that triggers switching from the defective column to the redundant column, according to an example.

FIG. 2A illustrates an AI engine including logic for switching from a defective column to the redundant column in the AI engine array, according to an example.

FIG. 2B illustrates the components of a bypass circuit or switching logic used to switch from the defective column to redundant column, according to an example.

FIG. 3 is a block diagram of a system-on-chip (SoC) that includes a data processing engine array and programmable logic, according to an example.

FIG. 4 illustrates a method for switching from the defective column to the redundant column in the AI engine array, according to an example.

FIG. 5 illustrates a method for re-routing signals, operations, memory interfaces, or data flows from the defective column to the redundant column, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the examples herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Artificial intelligence (AI) engines perform high-throughput, parallel processing for tasks such as machine learning, image recognition, and data analytics. An array of an AI engine usually has a grid-like structure of interconnected tiles, with each tile including a processing element, memory, memory interfaces, and communication interfaces. The AI engine arrays can be integrated into larger system-on-chip (SoC) architectures, where they serve as the computational backbone for AI-driven workloads. The scalability and performance of the AI engine arrays make them a preferred choice for advanced AI applications.

Despite their advantages, artificial intelligence engine (AIE) arrays are sensitive to defects that may occur during manufacturing. A defect in a single tile, such as a malfunctioning processing element, corrupted memory, or broken interconnect, can disrupt the operation of the entire AIE array. This is because the interconnected nature of the tiles demands all components to function correctly for seamless data flow and computation. In most current designs, a single defective tile can render the entire chip inoperable, as there is often no mechanism to bypass or isolate the faulty tile. This results in the discarding of the chip, leading to significant waste of resources and increased production costs.

The inability to tolerate defects within AIE arrays has substantial implications for chip yield and reliability. Manufacturing advanced semiconductor devices is a complex process, with inherent variability that can introduce defects at microscopic scales. As AIE arrays grow larger and more intricate to meet the increasing demands of AI workloads, the likelihood of defects also rises. The current approach of discarding entire chips due to single-tile malfunctions exacerbates production inefficiencies and poses challenges for scalability.

Addressing this issue involves designs that enable fault tolerance within AIE arrays. In view of such challenges, the examples present a method and system for including a redundant column within the AIE array. This redundant column replaces any defective column identified in the AIE array during boot time. When a defect is detected during boot time, a bypass circuit activates the redundant column, effectively isolating the malfunctioning column from the array. By redirecting data and computational operations to the redundant column, the overall functionality of the chip is preserved. This approach ensures that a single defect does not render the entire chip unusable, significantly enhancing manufacturing yields and reducing waste.

The bypass circuit enables dynamic reconfiguration of the AIE array. Upon detecting a defective tile, the bypass circuit re-routes communication and computation to the redundant column without the need for manual intervention. This seamless activation process avoids disruption to the chip’s operation and ensures that performance is maintained. Further, the redundant column design is scalable, allowing for its implementation in arrays of varying sizes without significant overhead.

Integrating at least one redundant column into AIE arrays offers multiple advantages. It not only improves the fault tolerance and reliability of the chip but also reduces production costs by minimizing waste. Further, this approach enhances the sustainability of chip manufacturing by reducing the number of discarded units due to minor defects. By ensuring that chips remain operational even in the presence of defects, this approach also supports the development of more robust and efficient AI systems, meeting the growing demands of AI-driven industries. As such, fault-tolerant AIE arrays can improve reliability and extend the operational lifetime of chips in the field.

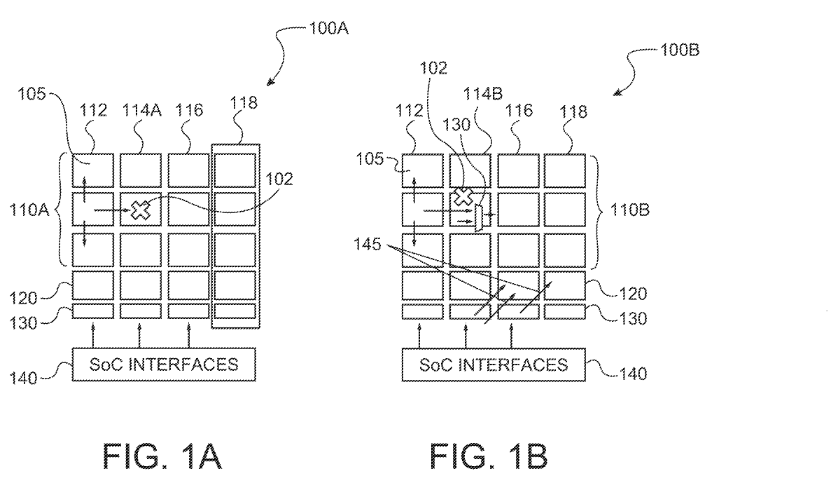

FIG. 1A illustrates a system including an artificial intelligence engine (AIE) array having a redundant column, according to an example.

The AIE configuration or system 100A depicts an array 110A. The array 110A can be, e.g., a 4x3 array including multiple tiles 105. The array 110A may be referred to as an AIE array. Any size array may be used. Each tile 105 is a processing unit that handles part of a computation in parallel with other tiles. The array 110A includes a first column 112, a second column 114A, a third column 116, and a fourth column 118. The fourth column 118 is a redundant column.

Each column of the array 110A is connected to a memory 120 and a bypass circuit 130 (FIG. 1B). The bypass circuit 130 may be referred to as switching logic. In one example, the bypass circuit 130 may be a multiplexer (MUX). The array 110A may be coupled to SoC interfaces 140 via communication paths 125 providing connectivity between the SoC interfaces 140 and the array 110A. The SoC interfaces 140 allow for flexible and dynamic data exchanges, enabling the system 100A to be programmed and controlled for various applications, e.g., AI/ML applications. The SoC interfaces 140 may be, e.g., network-on-chip (NoC) interfaces. The SoC interfaces 140 may be programmable logic (PL) or non-programmable logic. Programmable logic may include field programmable gate arrays (FPGAs) and non-programmable logic may include application-specific integrated circuits (ASICs). The SoC interfaces 140 are not limited to any type of logic, whether programmable or non-programmable.

The redundant column 118 refers to an extra column of processing tiles that is included as a backup or spare. The purpose of the redundant column 118 is to provide fault tolerance within the system 100A. The redundant column 118 includes the same number of tiles as the regular or primary columns, but these tiles are not used under normal conditions unless there is a failure in one of the regular or primary columns. The presence of the redundant column 118 ensures that the chip does not need to be discarded if a primary column fails. As such, during normal operation, the redundant column 118 is not engaged, and the array 110A operates in a normal manner with all its active columns contributing to the computation. When a defect or failure is detected in one of the primary columns, the redundant column 118 is activated to replace the defective one. The switch to the redundant column 118 is seamless with no disruption to the overall computation.

In one example, an error or malfunction or failure or defect 102 may be detected in, e.g., the second column 114A. The detection of the defect 102 triggers the bypass circuit 130 for the column flagged as defective or including a failure.

The switching logic or the bypass circuit 130 enables the chip to maintain functionality when defects are identified. In AIE arrays, each column is composed of multiple tiles that perform computational tasks in parallel. A defect in one of these tiles or its interconnects can disrupt the operation of the entire column, potentially compromising the array’s overall functionality. The bypass circuit 130 detects such defects and dynamically re-routes the data flow and computational tasks to a pre-configured redundant column. The bypass circuit 130 serves as the core mechanism to enable this functionality. The bypass circuit 130 operates as a decision-making and routing system, monitoring the health of each column within the array. When a defect is detected, the bypass circuit 130 isolates the defective column from the data path. The bypass circuit 130 then activates the redundant column 118 and re-routes the input and output signals, as well as memory interfaces, ensuring that operations continue without performance loss, as described below with reference to FIG. 1B.

FIG. 1B illustrates the AI engine array of FIG. 1A including the redundant column where a defect has been detected that triggers switching from the defective column to the redundant column, according to an example.

The AIE configuration or system 100B depicts an array 110B where the bypass circuit 130 has been triggered due to the detection of the defect 102 in the second column 114A of FIG. 1A. When the defect 102 is detected, the bypass circuit 130 deactivates the second column 114A rendering it as a defective column 114B and activates the redundant column 118. As such, the signals, operations, memory interfaces, and data are re-rerouted to the redundant column 118, as shown by arrows 145. As such, the computations are carried out using the first column 112, the third column 116, and the redundant column 118.

Stated differently, the 3x3 tile configuration can be extended to a 4x3 array by adding the redundant column 118. This additional column serves as a backup and is activated only when one of the primary columns is found defective. The redundant column 118, combined with dynamic switching logic or the bypass circuit 130, ensures that the array 110B remains fully operational even if a defect occurs in one of the primary columns. The redundant column 118 allows the array 110B to compensate for manufacturing defects or operational failures in any one primary column. This redundancy ensures that the chip remains functional, enhancing its reliability. Although the AIE array is built as a 4x3 configuration, it can be marketed and sold as a fault-tolerant 3x3 array. This gives manufacturers a competitive edge by offering high-reliability hardware at minimal additional cost.

In the AIE array architecture or system 100B, the redundant column 118 is included to enhance fault tolerance and improve manufacturing yield by compensating for defects in individual AIE tiles. This redundancy mechanism is activated during boot time, ensuring that a fully functional array is available before the AIE begins normal operation. Once the boot process completes, the AIE does not dynamically switch to the redundant column during runtime, meaning that any tile failures occurring after boot time are not mitigated through this redundancy mechanism.

In operation, during the boot sequence, the hardware performs a built-in self-test (BIST) and an initialization routine is used to verify the integrity of each AIE tile. If a defective tile is detected within the AIE array, the system 100B automatically remaps the workload to a pre-designated redundant column. This remapping process occurs at the configuration level, ensuring that the defective tile is effectively bypassed before the AIE array is activated for computational tasks. The remapping involves adjusting internal addressing and routing mechanisms so that software and applications perceive a fully functional array without any visible impact.

Alternatively, instead of a BIST, an electrically programmable fuse (eFuse) may be used to detect the defective tile. The eFuse is a one-time programmable element embedded within the AIE array that stores configuration and security settings permanently. eFuses are programmed during initial testing at the factory and cannot be changed afterward. During boot time, the eFuse values may be read to configure the AIE array before execution begins. For example, if a defective tile is detected during initial factory testing, an eFuse may be programmed to permanently indicate that the tile is faulty, and the system 100B can automatically remap computations to a redundant column during boot. This ensures that the system 100B initializes with a fully functional configuration without the need for runtime intervention.

The reason this switching occurs only during boot time is due to the architectural constraints and performance considerations of the AIE array. Runtime reconfiguration would introduce significant latency, which would involve dynamic rerouting of data paths and computational workloads, which may disrupt ongoing processing tasks. Additionally, AIE workloads are usually pipelined and scheduled in advance, making it impractical to introduce mid-operation tile substitutions without considerable performance penalties. Since the redundant column is utilized as part of the boot-time configuration process, the AIE relies on alternative resilience mechanisms rather than hardware redundancy to handle faults that occur after initialization.

Moreover, in one example, a user can specify a height of the defective column to allow for flexibility in defect management. For example, if a defective tile is detected, and entire columns have been specified to be replaced (i.e., column equals a height of the AIE array), then all the tiles within that column, including their compute, interconnects, and memory interfaces, are substituted by the redundant column. As such, a user may specify a full column replacement. This may be specified by making the redundant column height equal to the height of the intended AIE array. Alternatively, if a user specifies the height of the defective column to be less than the height of the AIE array, then if a defect is detected in a row of the column not covered by the user-specified height, a row-based skipping mechanism may be used.

Referring back to the switching logic or the bypass circuit 130, the bypass circuit 130 is a system of interconnected hardware components to dynamically re-route signals, operations, memory interfaces, or data flows in electronic circuits when a defect 102 (e.g., failure, or undesirable condition) is detected. The bypass circuit 130 ensures continued functionality of the chip by isolating faulty components and activating redundant or alternative pathways.

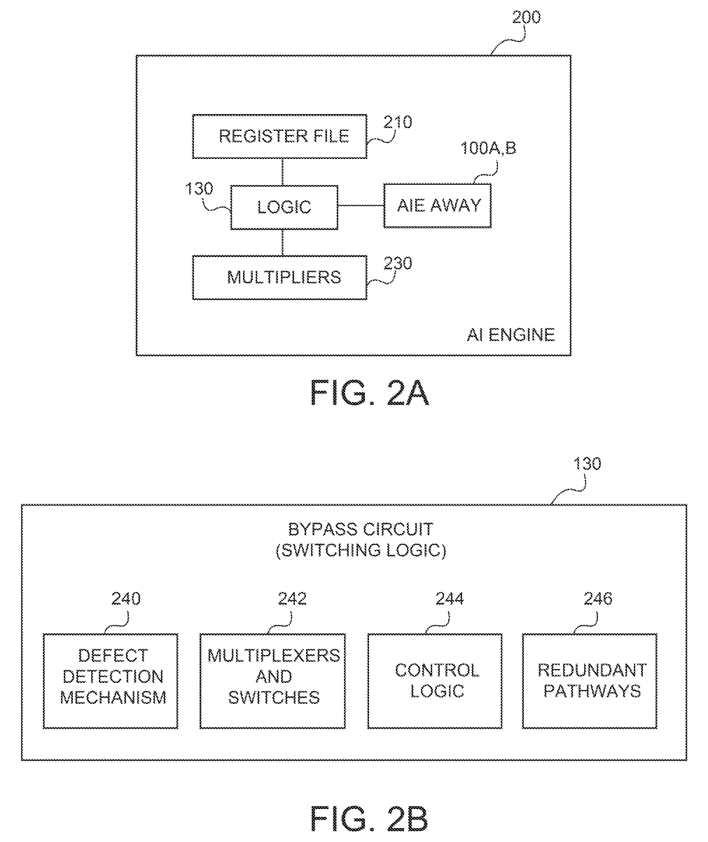

The bypass circuit 130 may include defect detection circuitry, re-routing logic, and dynamic configuration circuitry, as described in detail below with reference to FIG. 2B. Regarding the defect detection circuitry, a network of sensors or diagnostic units is embedded in each column to continuously monitor its performance. When an error is flagged, the bypass circuit 130 receives a signal identifying the defective column. Regarding the re-routing logic, the bypass circuit 130 uses multiplexers to redirect data, control signals, and memory interfaces from the defective column 114B to the redundant column 118. This process involves minimal latency, as the re-routing logic is performed in real time. Regarding the dynamic configuration circuitry, the redundant column 118 remains inactive under normal conditions to conserve power. Upon activation, the redundant column 118 is dynamically reconfigured to take over the role of the defective column 114B, ensuring seamless integration into the array's computational workload.

In other words, when a defect is detected in an AIE tile, resources are re-routed to a redundant column during boot time. This means that the defective AIE tile(s) are skipped, and their corresponding resources, including compute, interconnects, and memory interfaces, are adjusted to ensure the AIE array remains functional. For example, the memory interfaces are shifted to maintain a continuous and predictable memory map across the AIE array. When a defective tile is bypassed, the memory connections are remapped so that the software and hardware still perceives a contiguous memory space. The computations and memory accesses are thus redirected transparently, avoiding performance degradation.

Therefore, in operation, the redundant column 118 remains idle (or in an inactive state) during normal operations to conserve power and reduce wear. If one of the primary columns is identified as defective during boot time, the bypass circuit 130 isolates the defective column 114B and activates the redundant column 118. Data, control signals, and memory interfaces are re-routed seamlessly, ensuring uninterrupted functionality. For end users, the activation of the redundant column 118 is transparent, and the chip operates as a standard 3x3 array without noticeable degradation in performance.

The inclusion of the bypass circuit 130 or switching logic significantly enhances the fault tolerance of the AIE array. By isolating and bypassing defective columns, the AIE array can continue to function without necessitating the entire chip to be discarded. This capability not only improves manufacturing yield but also ensures that chips with minor defects remain fully operational. Additionally, the bypass circuit operates autonomously, involving no manual intervention, which reduces downtime and simplifies system or chip maintenance.

From an operational standpoint, the bypass circuit 130 is optimized for scalability and efficiency. In some examples, the bypass circuit 130 can handle multiple defects if multiple redundant columns are available, ensuring flexibility in array configurations. Furthermore, the bypass circuit 130 minimizes performance degradation, as it introduces only a marginal delay during the switching process.

In summary, a significant challenge with current AIE array designs is their sensitivity to defects. A defect in a single tile, arising from issues such as a malfunctioning processing element, damaged memory, or faulty interconnect, can disrupt the operation of the entire array. Because tiles in an AIE array are tightly interconnected, a defect in one tile can propagate across the system or chip, rendering the entire chip inoperable. In the absence of fault-tolerant mechanisms, such chips are often discarded, leading to substantial waste and increased manufacturing costs.

To address this issue, FIGS. 1A and 1B involve incorporating at least one redundant column into the AIE array. The at least one redundant column serves as a standby component that can replace any defective column within the AIE array. Upon identifying a defective column 114B, the bypass circuit 130 activates the redundant column 118, re-routing data, interconnects, memory interfaces, and computational tasks seamlessly (shown by the arrows 145). This approach ensures that the overall functionality of the array 110B is preserved, preventing the need to discard the entire chip due to localized defects. By isolating and replacing the defective column 114B dynamically, the chip remains operational and fully functional.

The bypass circuit 130 enables real-time detection of defects and automatically activates the redundant column 118 as a substitute. This process is performed without manual intervention, ensuring minimal disruption to the array’s operation. The redundant column 118 is integrated into the array 110B in a way that adds negligible complexity or overhead, maintaining the compactness and efficiency of the overall design. This solution is scalable, making it applicable to arrays of varying sizes and configurations.

The benefits of this redundant column design are manifold. First, it significantly improves the yield of AIE chips during manufacturing. Defective chips that would otherwise be discarded can now be salvaged, reducing waste and lowering production costs. This, in turn, makes AI hardware more sustainable and environmentally friendly by minimizing resource wastage. Additionally, the ability to tolerate defects enhances the reliability and robustness of AIE arrays, extending their operational lifespan and improving their suitability for mission-critical AI applications.

Also, this approach supports the scaling of AIE arrays to meet the growing demands of AI workloads. As arrays become larger and more complex, the probability of encountering defects increases. The inclusion of a redundant column mitigates this risk, enabling manufacturers to produce larger arrays without a proportional increase in defect-related losses. By addressing such limitation of current designs, the example approach offers a practical and cost-effective path toward more resilient and efficient AI systems.

Integrating a redundant column into an AIE array provides a robust solution for managing chip errors and defects in one or more columns. This approach ensures that minor manufacturing flaws or operational failures do not render the entire chip unusable.

By including a redundant column, chips with one or more defective columns can still be salvaged during manufacturing. Instead of discarding the entire chip due to localized defects, the bypass circuit re-routes operations, data, communications, and resources to the at least one redundant column. This significantly enhances manufacturing yield and reduces waste, leading to lower production costs and increased profitability by maximizing usable chips from each wafer.

The redundant column provides fault tolerance, ensuring the AIE array remains fully operational despite errors in primary columns. This is beneficial for applications involving high uptime and reliability, such as mission-critical AI systems and edge devices operating in harsh or variable conditions. Moreover, customers benefit from lower costs without compromising on performance. Chips with built-in redundancy reduce the risk of failure in deployed systems, resulting in lower maintenance costs and longer operational lifespans for AI hardware.

The redundant column design can also scale effectively with larger arrays. As AIE arrays grow in size to handle more complex workloads, the likelihood of defects increases. Including one or more redundant columns ensures flexibility to address multiple defects and scalability for larger AI workloads without exponentially increasing manufacturing losses.

In one example, the AIE array may include multiple redundant columns. The use of multiple redundant columns allows for better yield and improved fault tolerance, but the number of redundant columns impacts both the benefits and the trade-offs.

The advantages of having one redundant column include introducing minimal overhead in terms of silicon area, power consumption, and manufacturing cost compared to adding multiple redundant columns. This makes it an efficient solution for improving yield without significantly increasing production costs. Fewer redundant columns lead to a simpler chip design, making it easier to integrate into existing systems and to manage the routing of signals. The complexity of the switching and bypass circuits is reduced, which can improve design efficiency and reduce the likelihood of errors during manufacturing and operation. With only one redundant column, the chip consumes less power since the redundant column is inactive most of the time. A single redundant column provides an effective solution for chips that can tolerate one defect or failure in a column, ensuring minimal impact on performance while allowing the array to continue operating.

The drawbacks of having only one redundant column include that if more than one column experiences defects, the chip might still become inoperable. This limits the flexibility of the chip in environments where defects might affect multiple columns, especially in larger AIE arrays or when manufacturing yields are low. As the size of the AIE array increases, the likelihood of encountering multiple defective columns increases as well. A single redundant column may not be sufficient to address the failure of multiple columns, particularly for large-scale AI workloads, which use large and dense AIE arrays.

The advantages of having multiple redundant columns include that the AIE array can tolerate the failure of several columns without compromising functionality. This provides higher reliability, especially in mission-critical applications or environments with high defect rates in manufacturing. Larger AIE arrays with multiple redundant columns can scale more effectively, ensuring that if a defect occurs in one or two columns, there are still enough redundant resources available to keep the system or chip operational. This is particularly valuable for complex AI tasks and larger models that demand high computational power.

Multiple redundant columns reduce the risk of defects causing the chip to be discarded, further improving yield. Even if multiple defects are present across the AIE array, the chip can still be utilized, making this approach beneficial for manufacturing high-performance AI chips in bulk. With additional redundant columns, the likelihood of performance degradation due to defective columns is reduced. This ensures that the array continues to deliver optimal performance with minimal disruption, even in the case of multiple failures.

The drawbacks of having multiple redundant columns include using additional silicon area, leading to higher production costs. This may be noticeable when scaling the chip to larger sizes or when multiple redundant columns are needed across the entire array. The additional complexity in design and routing circuits also increases costs. While the redundant columns may remain inactive during normal operation, their presence consumes additional power when activated. If multiple redundant columns are used, the power consumption may increase, which could be a disadvantage for power-sensitive applications. More redundant columns introduce additional complexity in terms of routing signals, bypassing data paths, and managing the switching logic. This can increase the design time, as well as the chances of introducing errors during chip design and testing phases. Beyond a certain number of redundant columns, the incremental benefits of adding additional redundancy may be limited.

Therefore, the choice between having one or multiple redundant columns in an AIE array depends on the desired balance between cost, complexity, and fault tolerance. One redundant column is a cost-effective solution that provides basic fault tolerance, ideal for smaller systems or situations where defects are relatively rare and manageable. Multiple redundant columns offer enhanced fault tolerance and scalability, making them suitable for larger, more complex AI systems or in environments with higher defect rates or critical reliability needs. However, they come at the cost of increased complexity, power consumption, and manufacturing overhead.

FIG. 2A illustrates an AI engine including logic for switching from a defective column to the redundant column in the AI engine array, according to an example.

The AI engine 200 includes a register file 210, the switching logic (or the bypass circuit 130) for controlling the systems 100A, 100B, and multipliers 230.

The AI engine 200 is a specialized computational unit that accelerates tasks related to AI, such as ML, deep learning, and data processing. The AI engine 200 is optimized for high-speed, parallel computations, enabling efficient execution of AI workloads that involve massive data throughput and complex mathematical operations. AI engines are often part of larger systems, such as SoC architectures, and are integral to devices and applications in various fields.

The switching logic or the bypass circuit 130 enables real-time detection of defects and automatically activates the redundant column 118 as a substitute, as described above in detail.

The AI engine 200 enables the deactivation of a defective column in the AIE array and switching to a redundant column for activation.

FIG. 2B illustrates the components of a bypass circuit or switching logic used to switch from the defective column to redundant column, according to an example.

The bypass circuit 130 may include a defect detection mechanism 240, multiplexers and switches 242, control logic 244, and redundant pathways 246.

The defect detection mechanism 240 (or defect detection circuitry) may include embedded sensors or diagnostic units monitor the performance of system or chip components. The defect detection mechanism 240 may flag errors or deviations in expected performance, triggering the bypass circuit 130.

The multiplexers and switches 242 may be hardware elements responsible for re-routing data and control signals. Multiplexers select between normal and redundant pathways, ensuring smooth redirection.

The control logic 244 may process signals from the defect detection mechanism 240 and orchestrates re-routing decisions. The control logic 244 dynamically reconfigures the chip based on real-time inputs without manual intervention.

The redundant pathways 246 are predefined alternative routes or components, such as spare columns or units, and are activated to replace the malfunctioning part of the chip.

In the AIE configuration or system 100B, for instance, the bypass circuit 130 monitors each processing tile or column for defects. In operation, if a defect is detected, certain processes are triggered. For example, detection and isolation is performed where the bypass circuit 130 identifies the faulty column and isolates it to prevent disruption of the data flow or computation. Activation of redundancy where the redundant column 118, which is inactive under normal operation, is activated and configured to take over the role of the defective column 114B. Signal re-routing is performed where data, control signals, interconnections, and memory interfaces are seamlessly redirected to the redundant column 118 via the multiplexers and switches 242. This process is completed in real-time with minimal latency, ensuring that chip performance is not significantly impacted.

The bypass circuit 130 is thus beneficial as it ensures the chip continues to operate despite localized failures, salvages chips with minor defects, reducing waste and production costs, extends the operational life of hardware by dynamically bypassing defective components, and aids in supporting larger, more complex systems like AI arrays by mitigating the impact of manufacturing or operational defects.

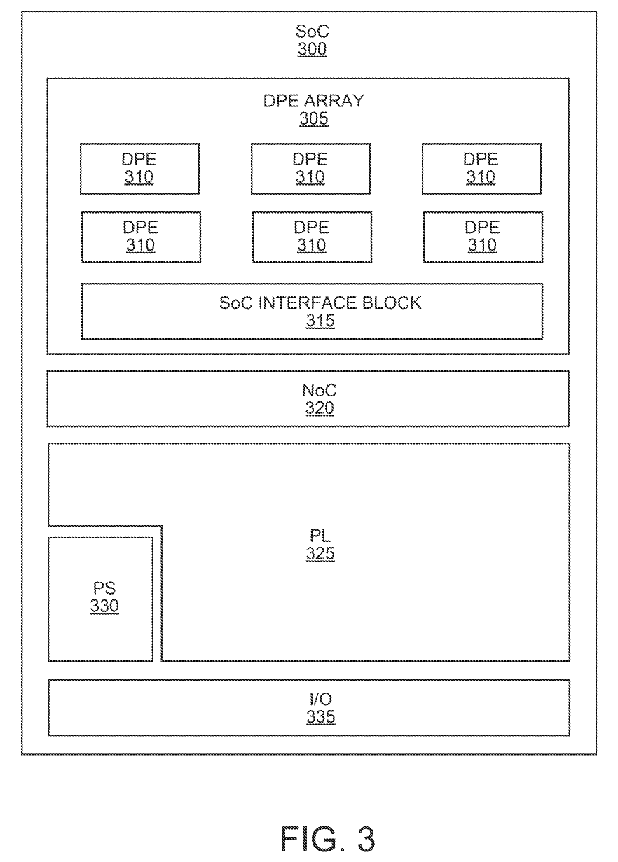

FIG. 3 is a block diagram of a SoC 300 that includes a data processing engine (DPE) array 305 and programmable logic (PL) 325, according to an example.

The DPE array 305 includes a plurality of DPEs 310 which may be arranged in a grid, cluster, or checkerboard pattern in the SoC 300. Although FIG. 3 illustrates arranging the DPEs 310 in a 2D array with rows and columns, the embodiments are not limited to this arrangement. Further, the array 305 can be any size and have any number of rows and columns formed by the DPEs 310.

In one example, the DPEs 310 are identical. That is, each of the DPEs 310 (also referred to as tiles or blocks) may have the same hardware components or circuitry. Further, the embodiments herein are not limited to DPEs 310. Instead, the SoC 300 can include an array of any kind of processing elements. For example, the DPEs 310 can be digital signal processing circuits, cryptographic circuits, forward error correction (FEC) circuits, or other specialized hardware for performing one or more specialized tasks.

In FIG. 3, the array 305 includes DPEs 310 that are all the same type (e.g., a homogeneous array). However, in another example, the array 305 may include different types of circuits. For example, the array 305 may include digital signal processing circuits, cryptographic circuits, graphic processing circuits, and the like. Regardless of whether the array 305 is homogenous or heterogeneous, the DPEs 310 can include direct connections between DPEs 310 which permit the DPEs 310 to transfer data directly as described in more detail below.

In one example, the DPEs 310 are formed from software-configurable hardened logic (i.e., are hardened). One advantage of doing so is that the DPEs 310 may take up less space in the SoC 300 relative to using programmable logic to form the hardware elements in the DPEs 310. That is, using hardened logic circuitry to form the hardware elements in the DPE 310 such as program memories, an instruction fetch/decode unit, fixed-point vector units, floating-point vector units, arithmetic logic units (ALUs), multiply accumulators (MAC), and the like can significantly reduce the footprint of the array 305 in the SoC 300. Although the DPEs 310 may be hardened, this does not mean the DPEs 310 are not programmable. That is, the DPEs 310 can be configured when the SoC 300 is powered on or rebooted to perform different functions or tasks.

The DPE array 305 also includes a SoC interface block 315 (also referred to as a shim) that serves as a communication interface between the DPEs 310 and other hardware components in the SoC 300. In this example, the SoC 300 includes a network on chip (NoC) 320 that is communicatively coupled to the SoC interface block 315. Although not shown, the NoC 320 may extend throughout the SoC 300 to permit the various components in the SoC 300 to communicate with each other. For example, in one physical implementation, the DPE array 305 may be disposed in an upper right portion of the integrated circuit forming the SoC 300. However, using the NoC 320, the array 305 can nonetheless communicate with, for example, PL 325, a processor subsystem (PS) 330, input/output (I/O) 335, or memory controller circuit (MC) (not show)n, which may be disposed at different locations throughout the SoC 300.

In addition to providing an interface between the DPEs 310 and the NoC 320, the SoC interface block 315 may also provide a connection directly to a communication fabric in the PL 325. In this example, the PL 325 and the DPEs 310 form a heterogeneous processing system since some of the kernels in a dataflow graph may be assigned to the DPEs 310 for execution while others are assigned to the PL 325. While FIG. 3 illustrates a heterogeneous processing system in a SoC, in other examples, the heterogeneous processing system can include multiple devices or chips. For example, the heterogeneous processing system could include two FPGAs or other specialized accelerator chips that are either the same type or different types. Further, the heterogeneous processing system could include two communicatively coupled SoCs.

In one example, the SoC interface block 315 includes separate hardware components for communicatively coupling the DPEs 310 to the NoC 320 and to the PL 325 that is disposed near the array 305 in the SoC 300. In one example, the SoC interface block 315 can stream data directly to a fabric for the PL 325. For example, the PL 325 may include an FPGA fabric which the SoC interface block 315 can stream data into, and receive data from, without using the NoC 320. That is, the circuit switching and packet switching described herein can be used to communicatively couple the DPEs 310 to the SoC interface block 315 and also to the other hardware blocks in the SoC 300. In another example, SoC interface block 315 may be implemented in a different die than the DPEs 310. In yet another example, DPE array 305 and at least one subsystem may be implemented in a same die while other subsystems and/or other DPE arrays are implemented in other dies. Moreover, the streaming interconnect and routing described herein with respect to the DPEs 310 in the DPE array 305 can also apply to data routed through the SoC interface block 315.

Although FIG. 3 illustrates PL 325 as one contiguous block, the SoC 300 may include multiple blocks of PL 325 (also referred to as logic sub-regions) that can be disposed adjacent to one another and/or at different locations in the SoC 300. Each logic sub-region (also referred to as a fabric sub-region) may include a set of configuration logic blocks (CLBs) that can include look-up tables (LUTs). In some embodiments, each logic sub-region is driven by a separate clock signal. In such embodiments, the logic sub-regions may be referred to as “clock regions.” PL 325 may include hardware elements that form a FPGA, programmable logic devices (PLD), and/or any other type of logic device that is reprogrammable. However, in other embodiments, the SoC 300 may not include any PL 325, e.g., the SoC 300 may be an ASIC.

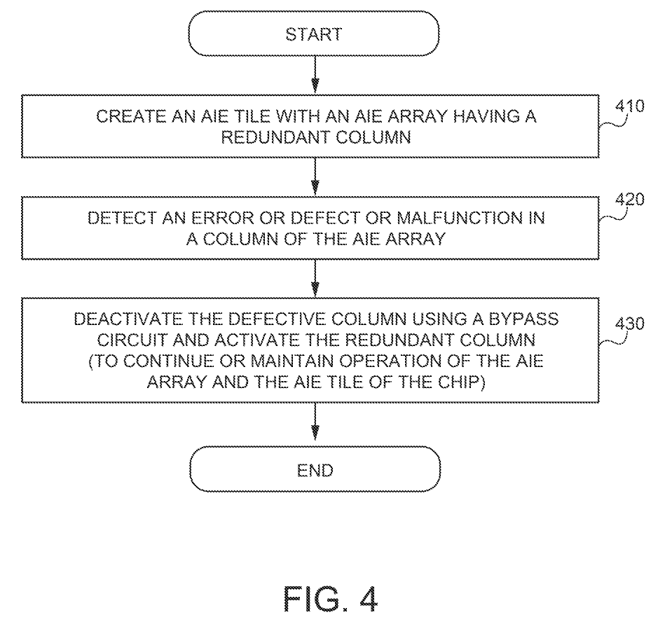

FIG. 4 illustrates a method for switching from the defective column to the redundant column in the AI engine array, according to an example.

At block 410, an AI engine comprises an AIE array with multiple tiles, the AIE array having at least one redundant column. The at least one redundant column replaces any defective column identified in the array.

At block 420, the bypass circuit identifies an error or defect or malfunction in a column of the AIE array. A defect in any tile typically renders the entire chip inoperable, necessitating its discard. This limitation not only reduces manufacturing yield but also increases production costs and contributes to resource waste.

At block 430, the bypass circuit deactivates the defective column and the redundant column is activated to continue or maintain operation of the AIE tile of the chip. When a defect is detected, the bypass circuit activates the redundant column, effectively isolating the malfunctioning column from the array. By redirecting data and computational operations to the redundant column, the overall functionality of the chip is preserved.

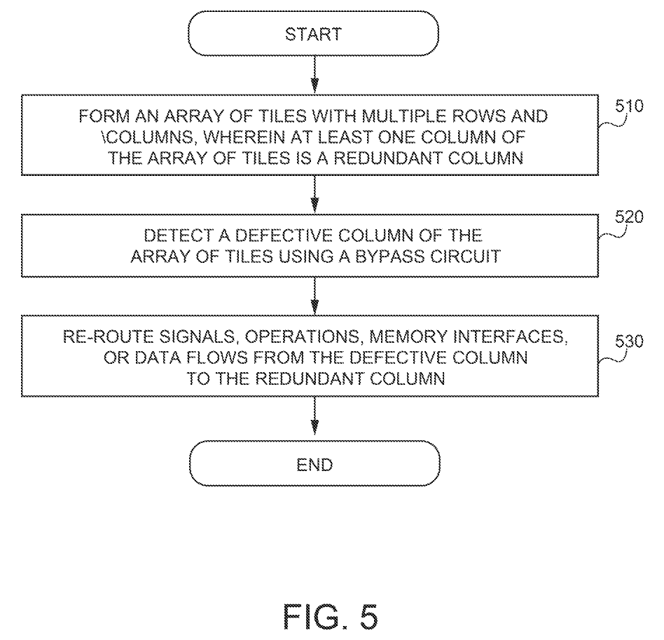

FIG. 5 illustrates a method for re-routing signals, operations, memory interfaces, or data flows from the defective column to the redundant column, according to an example.

At block 510, the AIE is configured to include an array of tiles with multiple rows and columns, where at least one column of the array of tiles is a redundant column. The redundant column 118 refers to an extra column of processing tiles that is included as a backup or spare. The purpose of the redundant column 118 is to provide fault tolerance within the system 100A. The redundant column 118 includes the same number of tiles as the regular or primary columns, but these tiles are not used under normal conditions unless there is a failure in one of the regular or primary columns.

At block 520, the bypass circuit detects a defective column in the array of tiles. In one example, the bypass circuit may be a multiplexer.

At block 530, the bypass circuit re-route signals, operations, memory interfaces, or data flows from the defective column to the at least one redundant column. By redirecting data, communication, and computational operations or resources to the at least one redundant column, the overall functionality of the chip is preserved.

In conclusion, the examples provide for a method and system for including at least one redundant column within the AIE array. The at least one redundant column replaces any defective column identified in the AIE array. When a defect is detected during boot time, a bypass circuit activates the at least one redundant column, effectively isolating the malfunctioning column from the AIE array. By redirecting at least data, interconnects, memory interfaces, communications, and computational operations to the at least one redundant column, the overall functionality of the chip is preserved. The example approach ensures that a single defect does not render the entire chip unusable, significantly enhancing manufacturing yields and reducing waste. The bypass circuit enables dynamic reconfiguration of the AIE array. Upon detecting a defective column, during boot time, the bypass circuit re-routes at least all communications and computations to the at least one redundant column without the need for manual intervention. This seamless activation process minimizes disruption to the chip’s operation and ensures that performance is maintained. Further, the at least one redundant column design is scalable, allowing for its implementation in AIE arrays of varying sizes without significant overhead.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the "C" programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An artificial intelligence (AI) engine comprising:
an array of tiles configured to form multiple rows and columns, wherein at least one column of the array of tiles is a redundant column; and
a bypass circuit configured to detect a defective column of the array of tiles and re-route at least signals, operations, memory interfaces, or data flows from the defective column to the redundant column.

2. The AI engine of claim 1, wherein the bypass circuit includes defect detection circuitry configured to monitor chip components and flag defects.

3. The AI engine of claim 1, wherein the bypass circuit includes multiplexers and switches to re-route the signals, operations, or data flows from the defective column to the redundant column.

4. The AI engine of claim 1, wherein the bypass circuit includes control logic for orchestrating re-routing decisions.

5. The AI engine of claim 1, wherein the bypass circuit isolates the defective column from the array of tiles.

6. The AI engine of claim 1, wherein each column of the array of tiles is coupled to a respective bypass circuit.

7. The AI engine of claim 1, wherein the bypass circuit is configured to provide seamless and non-disruptive data flow and computation.

8. A method comprising:
forming an array of tiles with multiple rows and columns, wherein at least one column of the array of tiles is a redundant column; and
detecting a defective column of the array of tiles using a bypass circuit; and
re-routing at least signals, operations, memory interfaces, or data flows from the defective column to the redundant column.

9. The method of claim 8, wherein the bypass circuit includes defect detection circuitry configured to monitor chip components and flag defects.

10. The method of claim 8, wherein the bypass circuit includes multiplexers and switches to re-route the signals, operations, or data flows from the defective column to the redundant column.

11. The method of claim 8, wherein the bypass circuit includes control logic for orchestrating re-routing decisions.

12. The method of claim 8, wherein the bypass circuit isolates the defective column from the array of tiles.

13. The method of claim 8, wherein each column of the array of tiles is coupled to a respective bypass circuit.

14. The method of claim 8, wherein the bypass circuit is configured to provide seamless and non-disruptive data flow and computation.

15. A system-on-chip (SoC) comprising:
one or more artificial intelligence (AI) engines, each AI engine including:
an array of tiles with multiple rows and columns including a redundant column; and
a bypass circuit configured to:
detect a defective column of the array of tiles; and
re-route communication and computation operations from the defective column to the redundant column.

16. The SoC of claim 15, wherein the bypass circuit includes defect detection circuitry configured to monitor chip components and flag defects.

17. The SoC of claim 15, wherein the bypass circuit includes multiplexers and switches to re-route the communication and computation operations from the defective column to the redundant column.

18. The SoC of claim 15, wherein the bypass circuit includes control logic for orchestrating re-routing decisions.

19. The SoC of claim 15, wherein each column of the array of tiles is coupled to a respective bypass circuit.

20. The SoC of claim 15, wherein the bypass circuit is configured to provide seamless and non-disruptive data flow and computation.
